(19) United States
(12) Patent Application Publication
(10) Pub. No.: US 2025/0285863 A1
(43) Pub. Date: Sep. 11, 2025

(54) METHOD OF FORMING PATTERN AND METHOD OF MANUFACTURING SEMICONDUCTOR DEVICE

(71) Applicant: SAMSUNG ELECTRONICS CO., LTD., Suwon-si (KR)

(72) Inventors: Junghwan Moon, Suwon-si (KR); Chan Hwang, Suwon-si (KR); Seongbo Shim, Suwon-si (KR); Moosong Lee, Suwon-si (KR)

(73) Assignee: SAMSUNG ELECTRONICS CO., LTD., Suown-si (KR)

(21) Appl. No.: 19/056,300

(22) Filed: Feb. 18, 2025

(30) Foreign Application Priority Data
Mar. 7, 2024 (KR) 10-2024-0032841

(51) Int. Cl. H01L 21/027; H01L 21/308; H01L 21/311

(52) U.S. Cl. CPC H01L 21/0274; H01L 21/3081; H01L 21/31144

(57) ABSTRACT

A method of forming a pattern includes forming an etching target layer on a substrate, forming an under layer on the etching target layer, forming a first resist pattern on the under layer, forming a second resist layer covering a side wall and a top surface of the first resist pattern and extending on a top surface of the under layer, forming a second resist pattern covering the side wall of the first resist pattern by removing a portion of the second resist layer on the top surface of the under layer, and performing an etching process using a resist structure as an etch mask, where the resist structure includes the first resist pattern and the second resist pattern.

### CROSS-REFERENCE TO RELATED APPLICATION

This application is based on and claims priority under 35 U.S.C. § 119 to Korean Patent Application No. 10-2024-0032841, filed on Mar. 7, 2024, in the Korean Intellectual Property Office, the disclosure of which is incorporated by reference herein in its entirety.

### BACKGROUND

Example embodiments of the disclosure relate to a method of forming a pattern, and more particularly, to a method of manufacturing a semiconductor device by using a resist pattern.

As the electronics industry further develops, the demand for high integration of semiconductor devices has increased. Accordingly, various problems arise in a patterning process of forming fine patterns, which makes it increasingly difficult to implement semiconductor devices. An exposure process using extreme ultraviolet (EUV) has been introduced to form fine patterns.

EUV may have a small number of photons per unit volume due to short wavelengths thereof. Accordingly, EUV resists may have a low absorption rate with respect to EUV. Patterns formed by using a EUV lithography process have a problem with a line edge roughness (LER).

Chemically amplified resists (CARs) have been used as resists in a EUV process. However, in a patterning process using CARs, problems have arisen in which fine patterns are formed with a uniform distribution due to increased resist blur, insufficient etch selectivity, or limitations in resolution.

Information disclosed in this Background section has already been known to or derived by the inventors before or during the process of achieving the embodiments of the present application, or is technical information acquired in the process of achieving the embodiments. Therefore, it may contain information that does not form the prior art that is already known to the public.

### SUMMARY

One or more example embodiments provide a method of forming a resist pattern with a uniform critical dimension and a uniform shape.

One or more example embodiments further provide a method of manufacturing a semiconductor device with improved precision and accuracy of a patterning process.

One or more example embodiments further provide a method of forming a fine pitch pattern with improved uniformity.

Additional aspects will be set forth in part in the description which follows and, in part, will be apparent from the description, or may be learned by practice of the presented embodiments.

According to an aspect of an example embodiment, a method of forming a pattern may include forming an etching target layer on a substrate, forming an under layer on the etching target layer, forming a first resist pattern on the under layer, forming a second resist layer covering a side wall and a top surface of the first resist pattern and extending on a top surface of the under layer, forming a second resist pattern covering the side wall of the first resist pattern by removing a portion of the second resist layer on the top surface of the under layer, and performing an etching process using a resist structure as an etch mask, where the resist structure may include the first resist pattern and the second resist pattern.

According to an aspect of an example embodiment, a method of forming a pattern may include forming an etching target layer, an under layer, and a first resist pattern on a substrate, wherein the first resist pattern overlaps a first portion of the etching target layer and does not overlap a second portion of the etching target layer, forming a second resist layer covering a side wall and a top surface of the first resist pattern and extending over the second portion of the etching target layer by performing a deposition process on the first resist pattern, forming a second resist pattern by performing a developing process on the second resist layer, and performing an etching process using the first resist pattern and the second resist pattern as an etch mask, where the forming of the second resist pattern includes removing the second resist layer that is over the second portion of the etching target layer.

According to an aspect of an example embodiment, a method of manufacturing a semiconductor device may include forming a device isolation layer, direct contacts, bit lines, conductive plugs, a landing layer and an under layer on a substrate, forming a mask pattern, an under pattern, and a resist structure on the landing layer, and forming landing pads by etching the landing layer exposed by the mask pattern, where the forming of the resist structure may include forming a first resist pattern on the under layer, forming a second resist layer covering a side wall and a top surface of the first resist pattern and extending on a top surface of the under layer, and forming a second resist pattern covering the first resist pattern by removing a portion of the second resist layer on the top surface of the under layer.

### BRIEF DESCRIPTION OF DRAWINGS

The above and other aspects, features, and advantages of certain example embodiments of the present disclosure will be more apparent from the following description taken in conjunction with the accompanying drawings, in which:

FIGS. 1A to 4C are diagrams illustrating a method of forming a pattern according to one or more embodiments;

FIGS. 5A to 5C are diagrams illustrating a method of forming a pattern according to one or more embodiments;

FIG. 6A is a plan view illustrating a first resist pattern according to one or more embodiments;

FIG. 6B is a plan view illustrating a resist structure according to one or more embodiments;

FIG. 7A is a plan view illustrating a layout of a semiconductor device according to one or more embodiments;

FIGS. 7B to 7D are cross-sectional views illustrating a method of manufacturing a semiconductor device according to one or more embodiments;

FIG. 8A is a plan view illustrating a layout of a semiconductor device according to one or more embodiments; and

FIG. 8B is a cross-sectional view taken along line III-III′ of FIG. 8A according to one or more embodiments.

### DETAILED DESCRIPTION

Hereinafter, example embodiments of the disclosure will be described in detail with reference to the accompanying drawings. The same reference numerals are used for the same components in the drawings, and redundant descriptions thereof will be omitted. The embodiments described herein are example embodiments, and thus, the disclosure is not limited thereto and may be realized in various other forms.

As used herein, expressions such as “at least one of,” when preceding a list of elements, modify the entire list of elements and do not modify the individual elements of the list. For example, the expression, “at least one of a, b, and c,” should be understood as including only a, only b, only c, both a and b, both a and c, both b and c, or all of a, b, and c.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

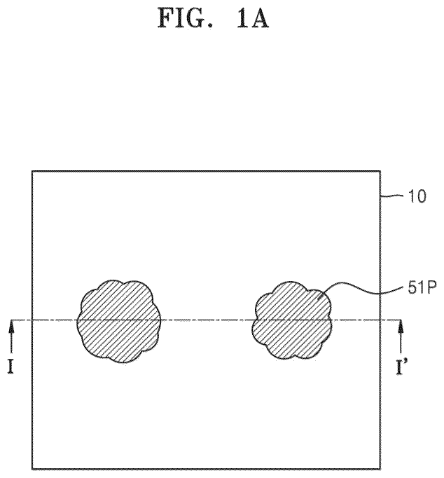

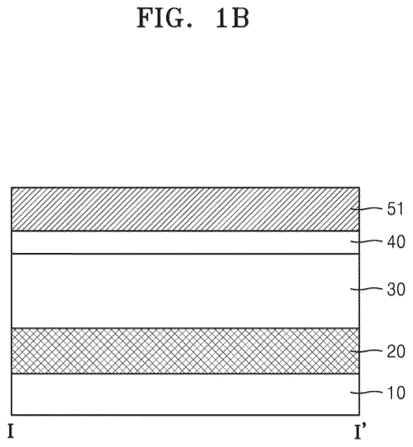

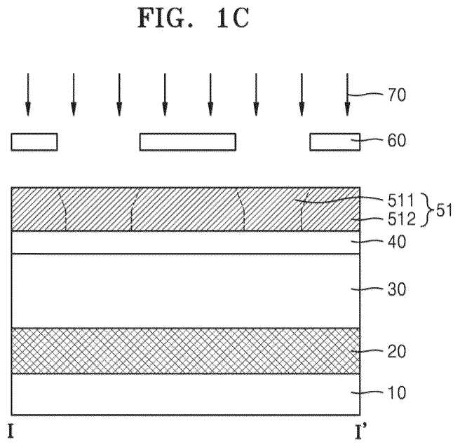

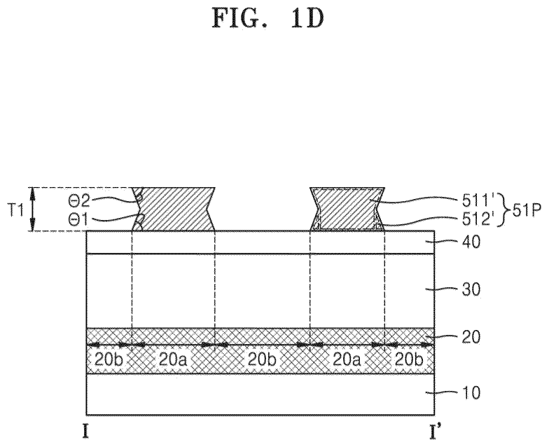

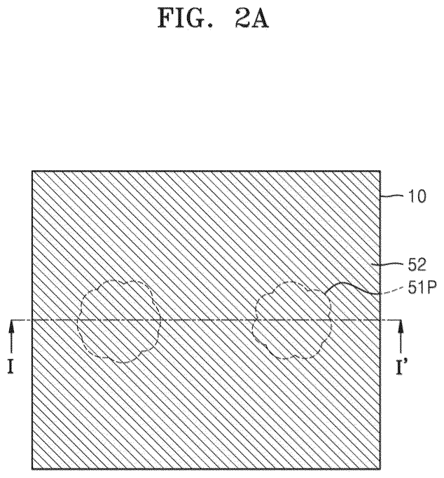

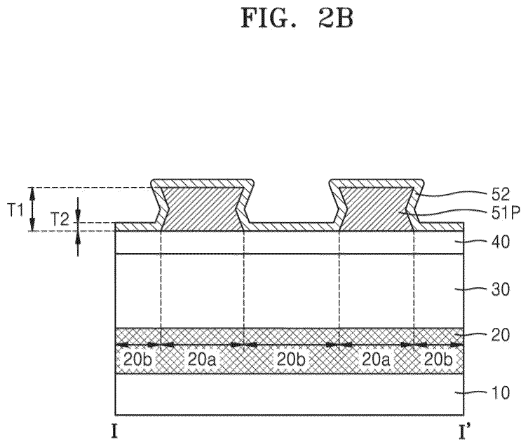

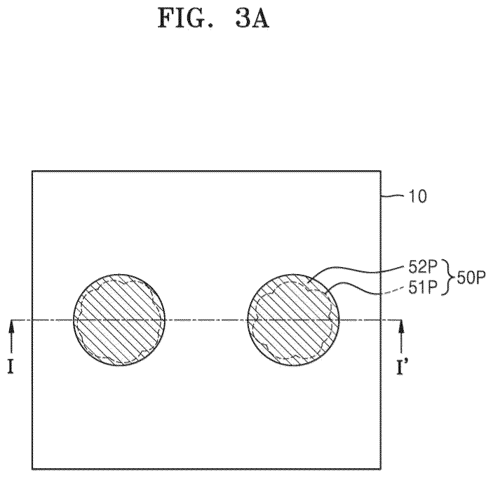

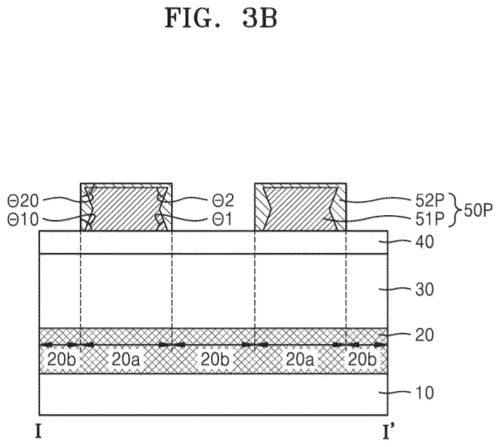

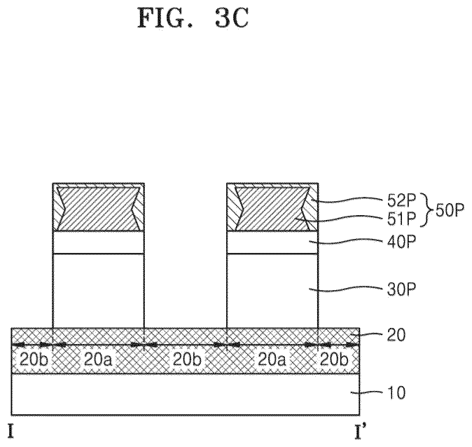

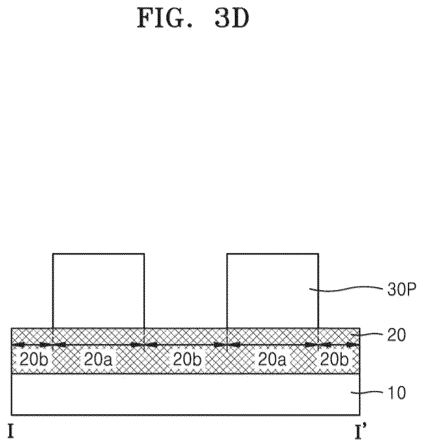

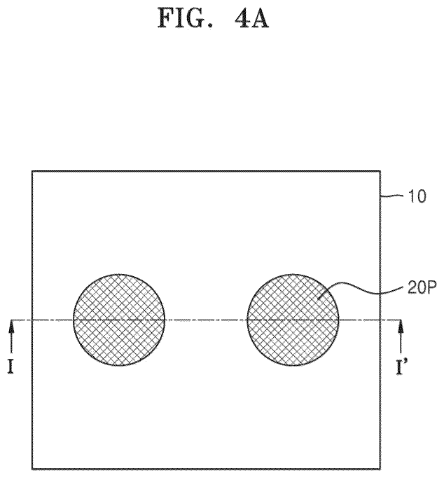

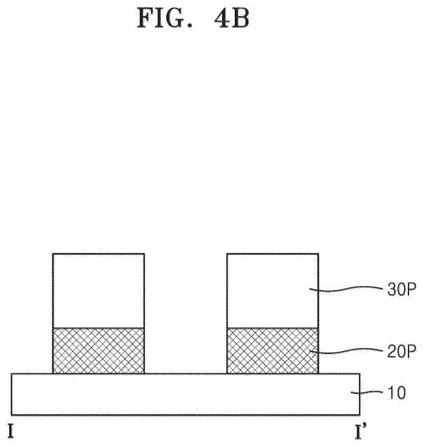

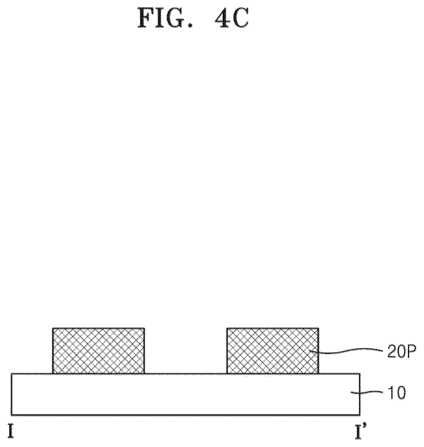

FIGS. 1A to 4C are diagrams illustrating a method of forming a pattern according to one or more embodiments. FIGS. 1A, 2A, 3A, and 4A are plan views illustrating the method of forming the pattern according to one or more embodiments. FIGS. 1B and 1C correspond to cross-sections taken along line I-I′ of FIG. 1A. FIG. 2B is a cross-section taken along line I-I′ of FIG. 2A. FIGS. 3B to 3D are cross-sections taken along line I-I′ of FIG. 3A. FIGS. 4B and 4C are cross-sections taken along line I-I′ of FIG. 4A.

Referring to FIGS. 1A and 1B, a substrate 10 on which an etching target layer 20, a mask layer 30, an under layer 40, and a first resist layer 51 are stacked may be prepared. The substrate 10 may include a semiconductor substrate or a semiconductor wafer.

The etching target layer 20 may be formed on a top surface of the substrate 10. For example, the etching target layer 20 may include a semiconductor material, a conductive material, and an insulating material, or a combination thereof. The semiconductor material may include silicon, germanium, doped silicon, and/or doped germanium. The conductive material may include a conductive metal nitride, a metal, and/or a metal-semiconductor compound. The conductive metal nitride may include titanium nitride and/or tantalum nitride. The metal may include tungsten, copper, aluminum, titanium, and/or tantalum. The metal-semiconductor compound may include tungsten silicide, cobalt silicide, and titanium silicide. The etching target layer 20 may be a single layer or a multi-layer. The etching target layer 20 may include a first portion 20a and a second portion 20b. That is, in a plan view and/or a cross-sectional view, the etching target layer 20 may include a first portion that is overlapped by a resist structure, and a second portion that is not overlapped by a resist structure, as will be described below. At least one additional layer may be provided between the substrate 10 and the etching target layer 20.

The mask layer 30 may be formed on the etching target layer 20. The mask layer 30 may be a single layer or a multi-layer. When the mask layer 30 is a multi-layer, the mask layer 30 may include a first mask layer, a second mask layer, and a third mask layer which are stacked. Each of the first mask layer and the third mask layer may include a silicon layer, a silicon oxide layer, a silicon nitride layer, a silicon oxynitride layer, or a metal layer. The metal layer may include a titanium layer, a tungsten layer, a titanium oxide, or a titanium nitride layer. The silicon layer may be an amorphous silicon layer, a single crystal silicon layer, or a polycrystalline silicon layer. For example, the first mask layer and the third mask layer may include the same material or different materials. The second mask layer may be provided between the first mask layer and the third mask layer. The second mask layer may include a different material from the first mask layer and the third mask layer. The second mask layer may include a spin-on hardmask (SOH) layer, a spin-on carbon (SOC) layer, or an amorphous carbon layer. A thickness of the second mask layer may be greater than a thickness of each of the first mask layer and the thickness of the third mask layer, but is not limited thereto.

The under layer 40 may be formed on the mask layer 30. The under layer 40 may include an organic material such as a polymer. The under layer 40 may support the first resist layer 51. The under layer 40 may attach the first resist layer 51 to the mask layer 30. A blocking layer may be further formed between the mask layer 30 and the under layer 40. In this case, the blocking layer may include at least one of carbon (C), silicon (Si), germanium (Ge), or tin (Sn).

The first resist layer 51 may be formed on the etching target layer 20 to cover a top surface of the under layer 40. The first resist layer 51 may include an extreme ultraviolet (EUV) resist compound. The first resist layer 51 may be formed using a non-chemically amplified resist (CAR). For example, the first resist layer 51 may include metal oxide. A second resist layer 52 may include an organic metal oxide. For example, the first resist layer 51 may include tin oxide, such as organotin oxide. When a resist layer includes a CAR, the resist layer may be formed by using a spin coating method. According to one or more embodiments where the first resist layer 51 includes the non-CAR such as metal oxide, forming the first resist layer 51 may include performing a deposition process such as chemical vapor deposition (CVD). Because the first resist layer 51 is formed through the deposition process, solvent content and additive content in a material for forming the first resist layer 51 may be reduced. Accordingly, the uniformity of the first resist layer 51 may be improved, and the productivity of a process of forming the first resist layer 51 may be improved. For example, the uniformity of a thickness of the first resist layer 51 may be improved.

Referring to FIGS. 1A and 1C, an exposure process may be performed on the first resist layer 51. The exposure process may be a EUV exposure process. A EUV ray 70 may be used as light in the exposure process. The EUV ray 70 may refer to a UV ray having a wavelength of about 12 nm to about 14 nm, such as, a wavelength of about 13.0 nm to about 13.9 nm, or a wavelength of about 13.4 nm to about 13.6 nm.

Before the EUV ray 70 is emitted, a photo mask 60 may be disposed on the first resist layer 51. The first resist layer 51 may include a first portion 511 and a second portion 512. The photo mask 60 may be disposed on the second portion 512 of the first resist layer 51. The photo mask 60 may include an opening. The opening of the photo mask 60 may expose the first portion 511 of the first resist layer 51. The EUV ray 70 may be emitted onto the first portion 511 of the first resist layer 51. As exposed to the EUV ray 70, a chemical bond or a chemical structure of a metal compound in the first portion 511 of the first resist layer 51 may change. The second portion 512 of the first resist layer 51 may not be exposed to the EUV ray 70. A chemical bond and a chemical structure of a metal compound in the second portion 512 of the first resist layer 51 may not change. Accordingly, after emission of the EUV ray 70 is completed, the first portion 511 of the first resist layer 51 may have a different chemical bond from the second portion 512.

Because the first resist layer 51 includes metal oxide, a dose of the EUV ray 70 in the exposure process may be reduced. Accordingly, the productivity of a pattern forming process and the throughput of exposure equipment may be further improved. The exposure equipment may be EUV high numerical aperture (NA) equipment, but is not limited thereto.

The metal oxide included in the first resist layer 51 may have a relatively high absorption rate with respect to the EUV ray 70. Accordingly, in the exposure process, the absorption amount of the EUV ray 70 in an upper portion of the first portion 511 of the first resist layer 51 may be greater than the absorption amount of the EUV ray 70 in a middle portion of the first portion 511 of the first resist layer 51 and the absorption amount of the EUV ray 70 in a lower portion of the first portion 511 of the first resist layer 51. Accordingly, the upper portion of the first portion 511 of the first resist layer 51 may have a greater width than the middle portion thereof. For example, a top surface of the first portion 511 of the first resist layer 51 may have a greater width than the middle portion thereof. The upper portion of the first portion 511 of the first resist layer 51 may have a greater width than the lower portion thereof.

After the exposure process, the photo mask 60 may be removed.

A post exposure bake (PEB) process of the first resist layer 51 may be performed. The PEB may include heat treating the first resist layer 51. The PEB process of the first resist layer 51 may be performed at a temperature of about 220° C. to about 240° C. The PEB process of the first resist layer 51 may be performed under nitrogen purge conditions. As a result of the PEB process, the first resist layer 51 may be denser.

Referring to FIGS. 1A and 1D, a first resist pattern 51P may be formed by performing a first developing process on the first resist layer 51. The first resist pattern 51P may be formed by using, for example, a EUV lithography process. The EUV lithography process may include the EUV exposure process of FIG. 1C and the first developing process. Forming the first resist pattern 51P may include removing the second portion 512 of the first resist layer 51. Because the first portion 511 of the first resist layer 51 has a different chemical bond or a different chemical structure from the second portion 512, the first portion 511 of the first resist layer 51 may not be removed during the first developing process.

The first resist pattern 51P may include a first portion 511′ and a second portion 512′. The first portion 511′ of the first resist pattern 51P may include the first portion 511 of the first resist layer 51 of FIG. 1C. The first resist pattern 51P may expose the top surface of the under layer 40. The first resist pattern 51P may overlap a first portion 20a of the etching target layer 20 and may not overlap a second portion 20b of the etching target layer 20 in a plan view. That is, the first resist pattern 51P may be formed over the first portion 20a and not formed over the second portion 20b. Although the figures depict an example of the first portion 20a and the second portion 20b, the second portion 20b of the etching target layer 20 may refer to any portion of the etching target layer 20 that is not overlapped by the first resist pattern 51P (or other resist patterns).

Because the first resist pattern 51P is formed through the EUV lithography process, the first resist pattern 51P may have a relatively narrow width. When the development of the first resist layer 51 is performed through a wet developing process using a liquid developing solution, the first resist pattern 51P may collapse. For example, due to the narrow width and a high aspect ratio of the first resist pattern 51P, the first resist pattern 51P may collapse due to the surface tension of the developing solution. According to one or more embodiments, the first developing process may be performed through a dry developing process using a development gas. That is, the first developing process may be a first dry developing process. For example, during the first developing process, the liquid developing solution may not be used. Because the first resist pattern 51P is formed through a dry developing process, collapse of the first resist pattern 51P may be prevented. A thickness T1 of the first resist pattern 51P may be about 260 Å to about 300 Å.

A development gas may include a halogen gas such as HBr. The concentration of the halogen gas may be about 70% to about 90%. The first developing process may be performed under temperature conditions of about −10° C. to about 10° C. Because concentration conditions of the halogen gas and temperature conditions satisfy the conditions described above, the first resist pattern 51P may be satisfactorily developed. For example, the second portion 512 of the first resist pattern 51P may be relatively satisfactorily removed, and the first resist pattern 51P may expose the top surface of the under layer 40.

A planar shape of the opening of the photo mask 60 in FIG. 1C may be designed to correspond to the desired planar shape of the first resist pattern 51P. For example, when it is desired to form the first resist pattern 51P in a circular planar shape, the planar shape of the opening of the photo mask 60 may be circular. However, when the first resist pattern 51P is formed through a lithography process including the EUV exposure process, the first resist pattern 51P may have a line edge roughness (LER). For example, the first resist pattern 51P may have a rough circular shape in a plan view.

At least a portion of a side wall of the first resist pattern 51P may not be perpendicular to a lower surface of the first resist pattern 51P. The first portion 511′ of the first resist pattern 51P may include the first portion 511 of the first resist layer 51, as described above. Accordingly, an upper portion of the first resist pattern 51P may have a greater width than a middle portion thereof. The second portion 512′ of the first resist pattern 51P may include a remaining portion or residue of the second portion 512 of the first resist layer 51 of FIG. 1C. The residue of the second portion 512 of the first resist layer 51 may include scum. The scum may be formed due to the insufficient development of the second portion 512 of the first resist layer 51 or due to an additive included in a resist compound of the first resist layer 51. The second portion 512′ of the first resist pattern 51P may be formed on a lower side wall of the first portion 511′ of the first resist pattern 51P. Accordingly, a lower portion of the first resist pattern 51P may have a greater width than the middle portion thereof. For example, a width of a top surface or a bottom surface of the first resist pattern 51P may be greater than a width of the middle portion of the first resist pattern 51P. At least one of an angle θ1 between the bottom surface and the side wall of the first resist pattern 51P and an angle θ2 between the top surface and the side wall of the first resist pattern 51P may be less than 75 degrees. For example, the angle θ1 between the bottom surface and the side wall of the first resist pattern 51P may be less than 75 degrees, and the angle θ2 between the top surface and the side wall of the first resist pattern 51P may be less than 75 degrees, but embodiments not limited thereto.

A plurality of first resist patterns 51P may be formed. For example, the first resist pattern 51P described thus far may be one of the plurality of first resist patterns 51P. Because the first resist patterns 51P are formed through the EUV lithography process, one of the first resist patterns 51P may have a different size or shape from the other one of the first resist patterns 51P.

Shapes of the first resist patterns 51P are not limited to those shown in FIGS. 1A and 1D and may be modified in various ways. Hereinafter, for simplicity of description, a single first resist pattern 51P is described.

Referring to FIGS. 2A and 2B, the second resist layer 52 may be formed on the side wall and the top surface of the first resist pattern 51P. The second resist layer 52 may extend over the second portion 20b of the etching target layer 20 and cover the top surface of the under layer 40. For example, the second resist layer 52 may conformally cover the side wall of the first resist pattern 51P, the top surface of the first resist pattern 51P, and the top surface of the under layer 40. A thickness T2 of the second resist layer 52 may be less than the thickness T1 of the first resist pattern 51P. For example, the thickness T2 of the second resist layer 52 may be about 50 Å to about 70 Å.

Forming the second resist layer 52 may include performing a deposition process on the first resist pattern 51P and the etching target layer 20. The deposition process may include, for example, a CVD process. The second resist layer 52 may be formed using the same resist material as a resist material of the first resist pattern 51P. The resist material may include a EUV resist material. For example, the second resist layer 52 may include tin oxide, such as organotin oxide. Because the second resist layer 52 is formed through the deposition process, a solvent content and an additive content in a material for forming the second resist layer 52 may be reduced. Accordingly, the uniformity of the second resist layer 52 may be improved, and the productivity of a process of forming the second resist layer 52 may be improved. For example, the second resist layer 52 may have the relatively uniform thickness T2.

An exposure process may not be performed on the second resist layer 52. Accordingly, even though the second resist layer 52 is manufactured using the same resist compound as the first resist pattern 51P, a chemical bond of a material of at least a portion of the second resist layer 52 may be different from a chemical bond of the material of the first resist pattern 51P. The first resist pattern 51P may be denser than the second resist layer 52. An interface between the first resist pattern 51P and the second resist layer 52 may be identified. The interface between the first resist pattern 51P and the second resist layer 52 may not be identified.

A bake process may be further performed on the second resist layer 52. The bake process of the second resist layer 52 may include heat treating the second resist layer 52. The bake process of the second resist layer 52 may be performed under a lower temperature condition than a temperature condition of the bake process of the first resist layer 51 described in the example of FIG. 1C. The bake process of the second resist layer 52 may be performed under a temperature condition of about 160° C. to about 200° C. For example, the bake process of the second resist layer 52 may be performed under nitrogen purge conditions. As a result of the bake process, the second resist layer 52 may become denser. However, after the bake process, the second resist layer 52 may be less dense than the first resist pattern 51P.

Referring to FIGS. 3A and 3B, a second resist pattern 52P may be formed by performing a second developing process on the second resist layer 52. Forming the second resist pattern 52P may include removing a portion of the second resist layer 52. The portion of the second resist layer 52 may include a portion on the etching target layer 20. The portion of the second resist layer 52 may be provided on the second portion 20b of the etching target layer 20. For example, the portion of the second resist layer 52 may cover the top surface of the under layer 40. Accordingly, the second resist pattern 52P may expose the top surface of the under layer 40. The second resist pattern 52P may be provided on the side wall of the first resist pattern 51P. The second resist pattern 52P may further extend over the top surface of the first resist pattern 51P. In one or more embodiments, the second resist pattern 52P may expose the top surface of the first resist pattern 51P. A thickness of the second resist pattern 52P may be less than the thickness T2 of the second resist layer 52 in FIG. 2B.

According to one or more embodiments, a second developing process may be performed through a dry developing process using a development gas. The second developing process may be a second dry developing process. During the second developing process, a liquid developing solution may not be used. Because the second resist pattern 52P is formed through the dry developing process, collapse of the second resist pattern 52P may be prevented.

The second developing process may be performed using the same development gas as the development gas of the first developing process described with reference to FIG. 1D. For example, during the second developing process, a halogen gas such as HBr may be used as a development gas. However, the concentration of the halogen gas in the second developing process may be less than the concentration of the halogen gas in the first developing process. For example, the concentration of the halogen gas in the second developing process may be about 5% to about 10%. When the concentration of the halogen gas is too high, the second resist layer 52 may be removed, and the first resist pattern 51P may be damaged (e.g., partially removed) during the second developing process. According to one or more embodiments, because the concentration of the halogen gas in the second developing process is 10% or less, damage to the first resist pattern 51P may be prevented. Because the concentration of the halogen gas in the second developing process is 5% or more, impurities may not remain on the top surface of the under layer 40. Accordingly, the second resist pattern 52P may satisfactorily expose the under layer 40. The impurities may include residue of the second resist layer 52.

The second developing process may be performed under a higher temperature condition than the temperature condition of the first developing process. For example, the second developing process may be performed under a temperature condition of about 20° C. to about 55° C. Because the temperature of the second developing process satisfies the condition described above, the second resist pattern 52P may be satisfactorily formed. For example, the second resist pattern 52P may expose the top surface of the under layer 40 without damaging the first resist pattern 51P.

According to one or more embodiments, a resist structure 50P including the first resist pattern 51P and the second resist pattern 52P may be formed. The second resist pattern 52P may improve the LER of the first resist pattern 51P. The resist structure 50P may have a more uniform width and a more uniform size than the first resist pattern 51P. For example, even though a middle portion of the first resist pattern 51P has less width than the top surface or the lower surface of the first resist pattern 51P, the second resist pattern 52P may cover a middle portion of the side wall of the first resist pattern 51P. Accordingly, a difference in the width of the resist structure 50P according to a vertical level may be less than a difference in the width of the first resist pattern 51P according to the vertical level. For example, a difference between the maximum width and the minimum width of the second resist pattern 52P may be less than a difference between the maximum width and the minimum width of the first resist pattern 51P. The width of the second resist pattern 52P may correspond to a gap between outer walls of the second resist pattern 52P.

An angle θ10 between a bottom surface and a side wall of the resist structure 50P may be greater than the angle θ1 between the bottom surface and the side wall of the first resist pattern 51P. For example, the angle θ10 between the bottom surface and the side wall of the resist structure 50P may be about 80 degrees to about 95 degrees. The bottom surface of the resist structure 50P may include the bottom surface of at least one of the first resist patterns 51P or the second resist pattern 52P. The side wall of the resist structure 50P may include the outer wall of the second resist pattern 52P. An angle θ20 between the top surface and the side wall of the resist structure 50P may be greater than the angle θ2 between the top surface and the side wall of the first resist pattern 51P. For example, the angle θ20 between the top surface and the side wall of the resist structure 50P may be about 80 degrees to about 95 degrees. When the second resist pattern 52P covers the top surface of the first resist pattern 51P, the top surface of the resist structure 50P may include the top surface of the second resist pattern 52P. When the second resist pattern 52P exposes the top surface of the first resist pattern 51P, the top surface of the resist structure 50P may include the top surface of the first resist pattern 51P.

According to one or more embodiments, because the second resist pattern 52P is provided, a shape of the resist structure 50P may be more uniform than a shape of the first resist pattern 51P. For example, even though the first resist pattern 51P has a rough circular shape in a plan view, the resist structure 50P may have a more uniform circular shape. For example, in a plan view, a deviation in a diameter of the second resist pattern 52P according to a direction may be less than a deviation in a diameter of the first resist pattern 51P according to the direction.

A plurality of resist structures 50P may be formed. For example, the resist structure 50P described above may be one of the plurality of resist structures 50P. A deviation in the size between the plurality of resist structures 50P may be less than a deviation in the size between the plurality of first resist patterns 51P. A deviation in the pitch between the plurality of resist structures 50P may be less than a deviation in the pitch between the plurality of first resist patterns 51P. Accordingly, even though the first resist patterns 51P have non-uniform shapes and sizes, as the second resist pattern 52P is formed, the resist structures 50P may have more uniform shapes and sizes.

According to an embodiment, the processes described in the examples of FIGS. 1A to 3B may be performed in the same chamber of the same equipment. For example, forming the first resist pattern 51P through the deposition process of the first resist layer 51 of FIG. 1B, the exposure process and the PEB process of the first resist layer 51 of FIG. 1C, and the first developing process of FIG. 1D, and forming the second resist pattern 52P through the deposition process of the second resist layer 52 of FIG. 2B and the second developing process of FIG. 3B may be performed in the same chamber. The chamber may be a vacuum chamber. The processes described in the examples of FIGS. 1A to 3B may be performed under vacuum conditions. The first resist pattern 51P and the second resist pattern 52P may not be exposed to air (e.g., oxygen). Accordingly, the resist structures 50P may be more uniformly formed. For example, the deviations in the sizes and shapes of the resist structures 50P may be reduced.

The shape of the second resist pattern 52P is not limited to those shown in FIGS. 3A and 3B and may be modified in various ways. Hereinafter, for simplicity of description, a single resist structure 50P is described.

Referring to FIGS. 3A and 3C, the under layer 40 and the mask layer 30 may be etched by performing an etching process using the first resist pattern 51P and the second resist pattern 52P as an etch mask. That is, the resist structure 50P may be used as an etch mask. An under pattern 40P may be formed by removing a portion of the under layer 40 exposed by the resist structure 50P through the etching process. The resist structure 50P may expose a portion of the mask layer 30. A mask pattern 30P may be formed by removing the exposed portion of the mask layer 30 through the etching process. The mask pattern 30P may expose the top surface of the second portion 20b of the etching target layer 20.

Referring to FIGS. 3A and 3D, a top surface of the mask pattern 30P may be exposed by removing the resist structure 50P and the under pattern 40P.

Referring to FIGS. 4A and 4B, a target pattern 20P may be formed by performing an etching process using the mask pattern 30P as an etch mask. For example, the second portion 20b of the etching target layer 20 may be etched. The first portion 20a of the etching target layer 20 may not be exposed to the etching process due to the mask pattern 30P. After the etching process, the first portion 20a of the etching target layer 20 may form the target pattern 20P.

Referring to FIGS. 4A and 4C, a top surface of the target pattern 20P may be exposed by removing the mask layer 30. The target pattern 20P may be formed at a position corresponding to the resist structure 50P of FIGS. 3A and 3C with the same or similar pitch. The target pattern 20P may have the same or similar shape and the same or similar size as the resist structure 50P.

According to one or more embodiments, the target pattern 20P may be a component of a semiconductor device. For example, the target pattern 20P may be a semiconductor pattern, a conductive pattern, or an insulating pattern within a semiconductor device.

The target pattern 20P may further include a metal element. The metal element may be the same as a metal element included in the first resist pattern 51P or a metal element included in the second resist pattern 52P of FIGS. 3A to 3C. The metal element included in each of the first resist pattern 51P and the second resist pattern 52P may partially remain in the target pattern 20P. The concentration of the metal element may be 1E11/cm³ or less. For example, the metal element may include tin.

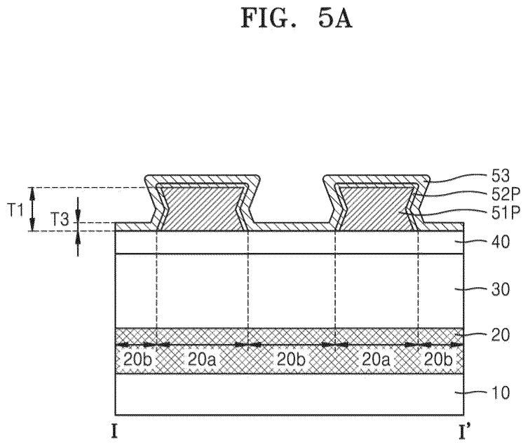

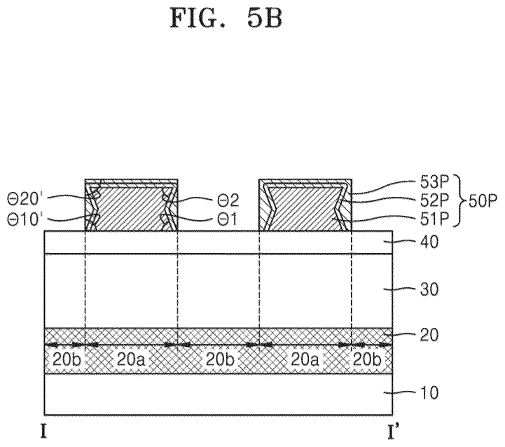

FIGS. 5A to 5C are diagrams illustrating a method of forming a pattern according to one or more embodiments. Hereinafter, redundant descriptions with those given above may be omitted.

Referring to FIG. 5A, the etching target layer 20, the mask layer 30, the under layer 40, the first resist pattern 51P, and the second resist pattern 52P may be sequentially formed on the substrate 10. The first resist pattern 51P may be formed by using substantially the same method as described in the examples of FIGS. 1B to 1D. The second resist pattern 52P may be formed by using substantially the same method as described in the examples of FIGS. 2A and 3B. However, despite the formation of the second resist pattern 52P, further improvement in an LER, shape uniformity, or dimension uniformity of the first resist pattern 51P may be required.

A third resist layer 53 may be formed on a side wall and a top surface of the first resist pattern 51P to cover the second resist pattern 52P. The third resist layer 53 may extend over a second portion 20b of the etching target layer 20 and cover a top surface of the under layer 40. For example, the third resist layer 53 may be formed on the side wall of the first resist pattern 51P, the top surface of the first resist pattern 51P, and the top surface of the under layer 40. The second resist pattern 52P may be disposed between the first resist pattern 51P and a third resist pattern 53P.

A thickness T3 of the third resist layer 53 may be less than the thickness T1 of the first resist pattern 51P. For example, the thickness T3 of the third resist layer 53 may be about 50 Å to about 70 Å.

Forming the third resist layer 53 may include performing a deposition process on the second resist pattern 52P and the etching target layer 20. The deposition process may include, for example, a CVD process. Because the third resist layer 53 is formed through a deposition process, a solvent content and an additive content in a material for forming the third resist layer 53 may be reduced. Accordingly, the uniformity of the third resist layer 53 may be improved, and the productivity of a process of forming the third resist layer 53 may be improved. For example, the third resist layer 53 may be formed with the relatively uniform thickness T3.

The third resist layer 53 may be formed using the same resist material as the first resist pattern 51P and the second resist pattern 52P. For example, the third resist layer 53 may include tin oxide such as organotin oxide. A chemical bond of a material of the second resist layer 52 may be substantially the same as a chemical bond of a second resist material. An interface between the second resist pattern 52P and the third resist layer 53 may not be identified, but is not limited thereto.

An exposure process may not be performed on the third resist layer 53. Accordingly, even though the third resist layer 53 is manufactured using the same resist compound as the first resist pattern 51P, a chemical bond of a material of the third resist layer 53 may be different from a chemical bond of a material of the first resist pattern 51P. The third resist pattern 53P may be less dense than the first resist pattern 51P.

A bake process may be further performed on the third resist layer 53. The bake process of the third resist layer 53 may include heat treating the third resist layer 53. For example, the bake process of the third resist layer 53 may be performed under nitrogen purge conditions. The bake process of the third resist layer 53 may be performed at a temperature of about 160° C. to about 200° C. As a result of the bake process, the third resist layer 53 may be denser. However, after the bake process, the third resist layer 53 may be less dense than the first resist pattern 51P. A density of the third resist pattern 53P may be substantially the same as a density of the second resist pattern 52P.

Referring to FIG. 5B, the third resist pattern 53P may be formed by performing a third developing process on the third resist layer 53. Forming the third resist pattern 53P may include removing a portion of the third resist layer 53. The portion of the third resist layer 53 may include a portion on the etching target layer 20. For example, the portion of the third resist layer 53 may a portion covering the top surface of the under layer 40. Accordingly, the third resist pattern 53P may expose the top surface of the under layer 40. The third resist pattern 53P may be provided on the side wall of the first resist pattern 51P to cover the second resist pattern 52P. The third resist pattern 53P may further extend over the top surface of the first resist pattern 51P or the top surface of the second resist pattern 52P. In one or more embodiments, the third resist pattern 53P may expose the top surface of the first resist pattern 51P or the top surface of the second resist pattern 52P. A thickness of the third resist pattern 53P may be less than the thickness T3 of the third resist layer 53 in FIG. 5A.

According to one or more embodiments, the third developing process may be performed by a dry developing process using a development gas. During the developing process, a liquid developing solution may not be used. Because the third resist pattern 53P is formed through a dry developing process, collapse of the third resist pattern 53P may be prevented.

The third developing process may be performed by using substantially the same method as the second developing process described with reference to FIG. 2B. For example, during the third developing process, a halogen gas such as HBr may be used as the development gas. The concentration of the halogen gas in the third developing process may be substantially the same as the concentration of the halogen gas in the second developing process. The concentration of the halogen gas in the third developing process may be less than the concentration of the halogen gas in the first developing process described with reference to FIG. 1D. For example, the concentration of halogen gas in the third developing process may be about 5% to about 10%. According to one or more embodiments, because the concentration of halogen gas in the third developing process is 10% or less, damage to the first resist pattern 51P or the second resist pattern 52P may be prevented. Because the concentration of halogen gas in the third developing process is 5% or more, impurities may not remain on the top surface of the under layer 40. That is, the third resist pattern 53P may satisfactorily expose the under layer 40. The impurities may include residue of the third resist layer 53.

The third developing process may be performed under substantially the same temperature conditions as the second developing process. The second developing process may be performed under a higher temperature condition than temperature condition the first developing process. For example, the third developing process may be performed under a temperature condition of about 20° C. to about 55° C. Because the temperature of the third developing process satisfies the above conditions, the third resist pattern 53P may expose the top surface of the under layer 40 without damaging the first resist pattern 51P.

According to one or more embodiments, the resist structure 50P including the first resist pattern 51P, the second resist pattern 52P, and the third resist pattern 53P may be formed. The third resist pattern 53P may improve an LER of each of the first resist pattern 51P and the second resist pattern 52P. The resist structure 50P may have a more uniform width and a more uniform size than the first resist pattern 51P. For example, a difference in a width of the resist structure 50P according to a vertical level may be less than a difference in a width of the first resist pattern 51P according to the vertical level. For example, a difference between the maximum width and the minimum width of the third resist pattern 53P may be less than a difference between the maximum width and the minimum width of the second resist pattern 52P. The difference between the maximum width and the minimum width of the third resist pattern 53P may be less than a difference between the maximum width and the minimum width of the first resist pattern 51P.

For example, an angle θ10′ between a bottom surface and a side wall of the resist structure 50P may be greater than the angle θ1 between a bottom surface and a side wall of the first resist pattern 51P. For example, the angle θ10′ between the bottom surface and the side wall of the resist structure 50P may be about 80 degrees to about 95 degrees. The side wall of the resist structure 50P may include an outer wall of the third resist pattern 53P. An angle θ20′ between a top surface and the side wall of the resist structure 50P may be greater than the angle θ2 between a top surface and the side wall of the first resist pattern 51P. For example, the angle θ20′ between the top surface and the side wall of the resist structure 50P may be about 80 degrees to about 95 degrees. The top surface of the resist structure 50P may include a top surface of the third resist pattern 53P. When the third resist pattern 53P exposes the top surface of the first resist pattern 51P or the top surface of the second resist pattern 52P, the top surface of the resist structure 50P may include the exposed top surface of the first resist pattern 51P or the exposed top surface of the second resist pattern 52P.

According to one or more embodiments, because the third resist pattern 53P is provided, a shape of the resist structure 50P may be more uniform than a shape of the first resist pattern 51P.

A plurality of resist structures 50P may be formed. A deviation in the size between the plurality of resist structures 50P may be less than a deviation in the size between the plurality of first resist patterns 51P. A deviation in the pitch between the plurality of resist structures 50P may be less than a deviation in the pitch between the plurality of first resist patterns 51P. As the third resist pattern 53P is formed, the resist structures 50P may have more uniform shapes and sizes.

According to one or more embodiments, because a solvent content and an additive content in a material for forming the third resist layer 53 are reduced, the third resist layer 53 may be uniformly developed. Accordingly, the uniformity of the sizes and shapes of the resist structures 50P may be further improved.

The shape of the third resist pattern 53P may be modified in various ways. Hereinafter, for simplicity of description, a single resist structure 50P is described.

Referring to FIG. 5C, the under layer 40 and the mask layer 30 may be etched by performing an etching process using the first resist pattern 51P, the second resist pattern 52P, and the third resist pattern 53P as an etch mask. That is, the resist structure 50P may be used as an etch mask. The under pattern 40P and the mask pattern 30P may be formed by sequentially removing a portion of the under layer 40 and a portion of the mask layer 30 exposed by the resist structure 50P through the etching process. The mask pattern 30P may expose a portion of the top surface of the second portion 20b of the etching target layer 20.

Thereafter, referring again to FIG. 4B, a top surface of the mask pattern 30P may be exposed by removing the resist structure 50P and the under pattern 40P.

Referring again to FIG. 4C, the target pattern 20P may be formed by performing an etching process using the mask pattern 30P as an etch mask.

Despite the formation of the third resist pattern 53P in FIG. 5B, further improvement in an LER of the first resist pattern 51P may be required. In this case, a fourth resist pattern may be further formed on the third resist pattern 53P and the resist structure 50P may further include the fourth resist pattern. The etching process of FIG. 5C may be performed using the first resist pattern 51P, the second resist pattern 52P, the third resist pattern 53P, and the fourth resist pattern as an etch mask. The number of the stacked first resist patterns 51P, second resist patterns 52P, third resist patterns 53P, and fourth resist patterns is not limited to that shown and may be modified in various ways.

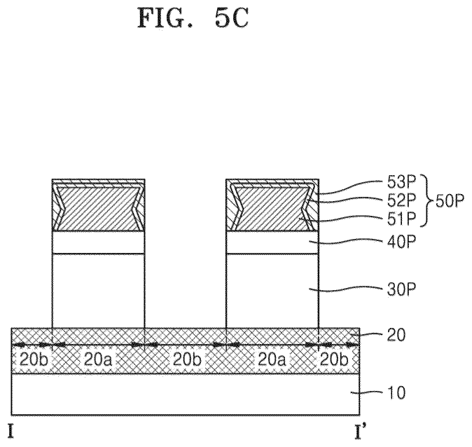

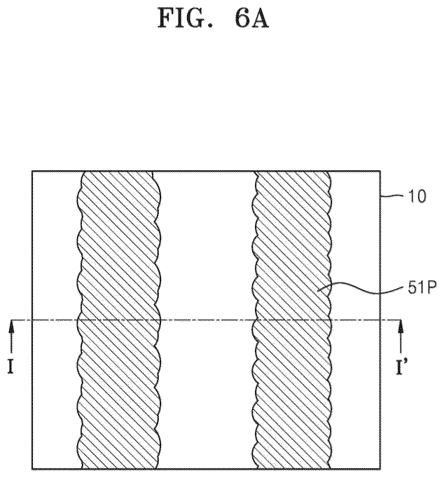

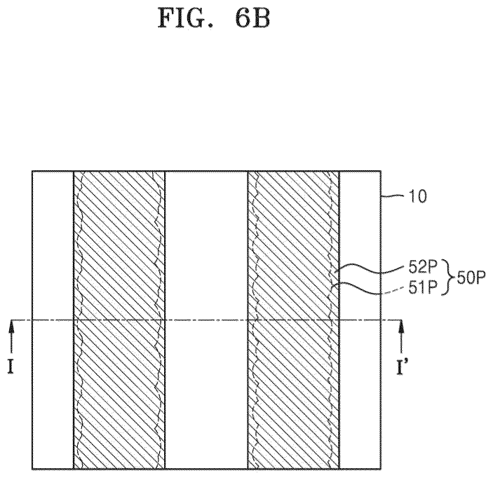

FIG. 6A is a plan view illustrating the first resist pattern 51P according to one or more embodiments. FIG. 6B is a plan view illustrating the resist structure 50P according to one or more embodiments. A cross-section taken along line I-I′ in FIG. 6A may correspond to FIG. 1D. A cross-section taken along line I-I′ in FIG. 6B may correspond to FIG. 3B.

Referring to FIG. 6A, the first resist pattern 51P may have a line shape in a plan view. For example, the first resist pattern 51P may extend in a first direction. The first direction may be parallel to a lower surface of the substrate 10. A planar shape of the first resist pattern 51P may be modified in various ways.

Referring to FIG. 6B, the resist structure 50P may be formed by forming the second resist pattern 52P on the first resist pattern 51P. The resist structure 50P may include the first resist pattern 51P and the second resist pattern 52P. The second resist pattern 52P may improve an LER of the first resist pattern 51P. The resist structure 50P may have a more uniform width and size than the first resist pattern 51P. A shape of the resist structure 50P may be more uniform than a shape of the first resist pattern 51P.

A plurality of resist structures 50P may be formed. The plurality of resist structures 50P may be spaced apart in a second direction. The second direction may be parallel to the lower surface of the substrate 10 and intersect the first direction. A deviation in the size between the plurality of resist structures 50P may be less than a deviation in the size between the plurality of first resist patterns 51P.

Hereinafter, a method of manufacturing a semiconductor device according to one or more embodiments is described.

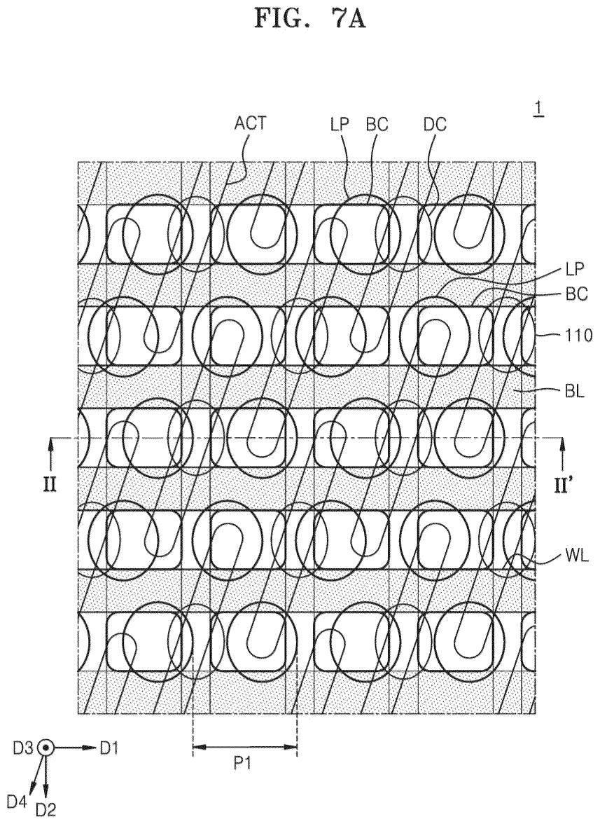

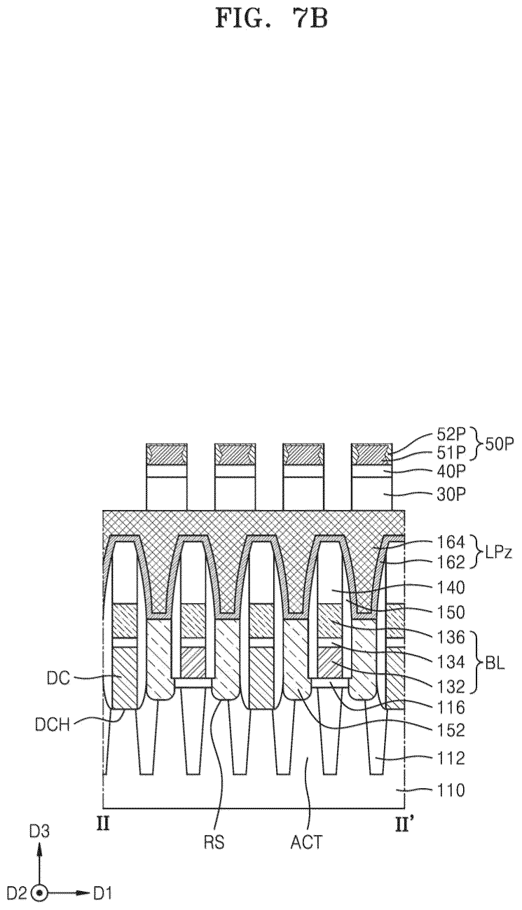

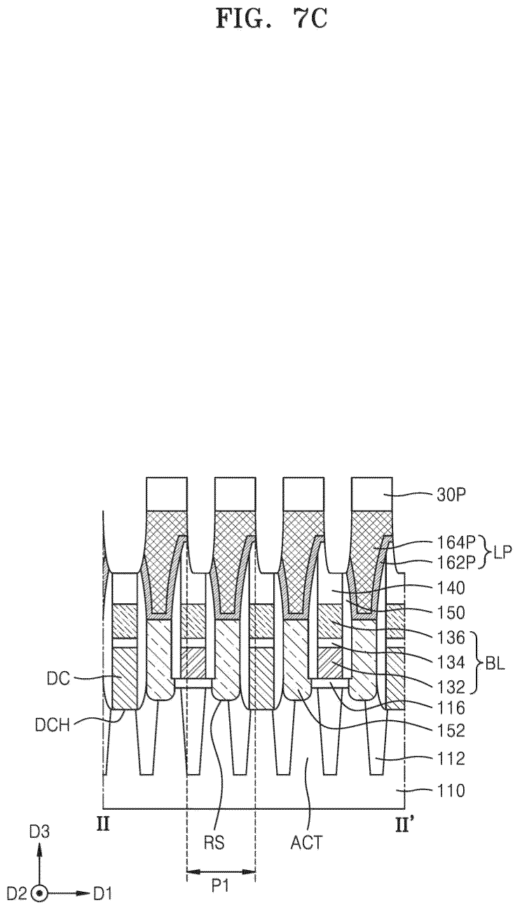

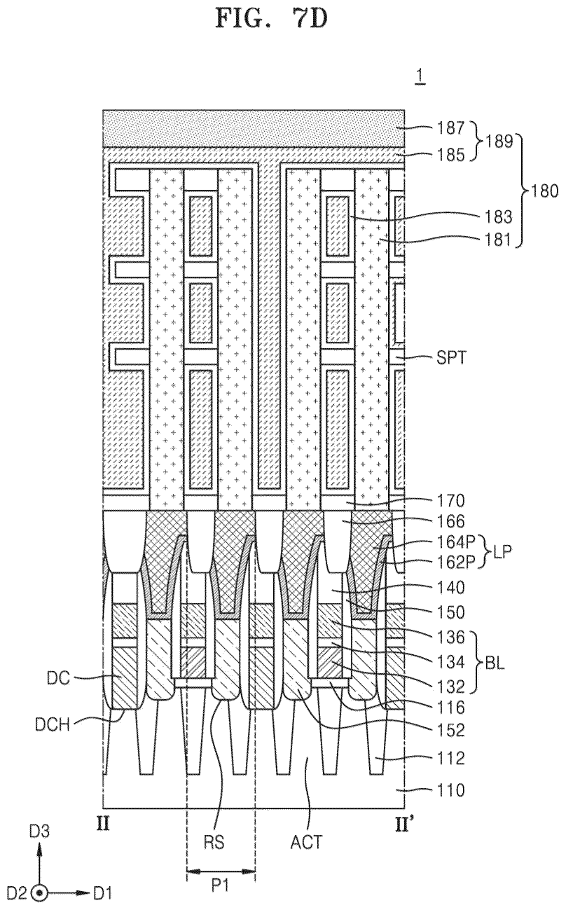

FIG. 7A is a plan view illustrating a layout of a semiconductor device 1 according to one or more embodiments. FIGS. 7B to 7D are cross-sectional views illustrating a method of manufacturing the semiconductor device 1 according to one or more embodiments, and correspond to cross-sections taken along line II-II′ of the semiconductor device 1 of FIG. 7A. Hereinafter, redundant descriptions with those given above are omitted.

Referring to FIGS. 7A and 7B, a device isolation layer 112, a plurality of word lines WL, a plurality of bit lines BL, and direct contacts DC may be formed on the substrate 110. The substrate 110 may have a memory cell area. For example, the memory cell area of the substrate 110 may be an array area of volatile memory cells of a dynamic random-access memory (DRAM) device. The substrate 110 may be a semiconductor wafer. The substrate 110 may include, for example, a semiconductor material such as silicon or germanium. For another example, the substrate 110 may include a compound semiconductor such as silicon carbide (SiC), gallium arsenide (GaAs), indium arsenide (InAs), and/or indium phosphide (InP). For another example, the substrate 110 may be a silicon on insulator (SOI) substrate. In addition, the substrate 110 may include a conductive area, for example, a well doped with an impurity or an area doped with an impurity.

A second direction D2 may be perpendicular to a first direction D1 in a plan view. A third direction D3 may be parallel to a lower surface of the substrate 110 and intersect the first direction D1 and the second direction D2. The third direction D3 may be substantially perpendicular to the lower surface of the substrate 110. The third direction D3 may be a vertical direction. A fourth direction D4 may intersect the first direction D1, the second direction D2, and the third direction D3. The fourth direction D4 may be a diagonal direction.

The device isolation layer 112 may be formed on the substrate 110 to define a plurality of active areas ACT. The device isolation layer 112 may include silicon oxide, silicon nitride, or a combination thereof.

As shown in FIG. 7A, the plurality of active areas ACT may extend parallel to the fourth direction D4 in a plan view. The plurality of word lines WL may extend in the first direction D1 across the plurality of active areas ACT.

A portion of the substrate 110 may be removed, and direct contact holes DCH may be formed in the substrate 110. The direct contact holes DCH may expose the active areas ACT. Conductive materials may be provided in the direct contact holes DCH to form the direct contacts DC. The bit lines BL may be formed on the direct contacts DC. The direct contacts DC may be respectively connected to the plurality of active areas ACT. The direct contacts DC may include doped polysilicon. For example, the direct contacts DC may include polysilicon that may include a relatively high concentration of impurities such as phosphorus (P), arsenic (As), bismuth (Bi), and/or antimony (Sb).

The bit lines BL may be formed on the substrate 110 and the direct contacts DC. The plurality of bit lines BL may be connected to the plurality of active areas ACT through the plurality of direct contacts DC. The plurality of bit lines BL may extend in the second direction D2 on the plurality of word lines WL. Each of the bit lines BL may include a first lower conductive pattern 132, a first middle conductive pattern 134, and a first upper conductive pattern 136. The first lower conductive pattern 132, the first middle conductive pattern 134, and the first upper conductive pattern 136 may be stacked on the substrate 110. The first lower conductive pattern 132 may include doped polysilicon. The first middle conductive pattern 134 and the first upper conductive pattern 136 may each independently include at least one of TIN, TiSiN, W, tungsten silicide, and a combination thereof. For example, the first middle conductive pattern 134 may include TIN, TiSiN, or a combination thereof, and the first upper conductive pattern 136 may include tungsten.

Dielectric patterns 116 may be formed between the active areas ACT and the bit lines BL. Each of the dielectric patterns 116 may cover a lower surface of the corresponding first lower conductive pattern 132. The dielectric patterns 116 may each include a high dielectric material. The high dielectric material may have a higher dielectric constant than silicon oxide, silicon nitride, silicon oxynitride, or silicon oxide.

A plurality of insulating capping layers 140 may be formed on the bit lines BL to cover top surfaces of the bit lines BL. The plurality of insulating capping layers 140 may extend in the second direction D2 on the plurality of bit lines BL. Bit line spacers 150 may be formed on both side walls of each of the plurality of bit lines BL. The bit line spacers 150 may cover side walls of the bit lines BL and side walls of the insulating capping layers 140. The bit line spacers 150 may extend in a direction parallel to the second direction D2 in a plan view. Some of the bit line spacers 150 may extend further into the corresponding direct contact holes DCH and cover both side walls of the corresponding direct contact holes DC.

Insulating fences may be formed between the bit lines BL. Contact spaces may be provided between the bit lines BL and between the insulating fences. Recess portions RS may be formed by removing portions of the substrate 110 below the contact spaces. The recess portions RS may expose the active areas ACT between the bit lines BL. Conductive plugs 152 may be formed by filling each of the recess portions RS and the contact spaces with a conductive material. The conductive plugs 152 may be provided in the recess portions RS and may extend in the fourth direction D4 in a plan view. The insulating fences may be disposed between the conductive plugs 152.

Buried contacts BC of FIG. 7A may include the conductive plugs 152 of FIG. 7B. The buried contacts BC may be disposed between the plurality of bit lines BL. For example, each of the buried contacts BC may be disposed between two neighboring bit lines BL among the plurality of bit lines BL. The buried contacts BC may be arranged in the first direction D1 and the second direction D2 in a plan view.

A landing layer LPz may be formed on the conductive plugs 152 and the insulating capping layers 140. The landing layer LPz may further extend onto outer walls of the bit line spacers 150. The landing layer LPz may include a barrier layer 162 and a conductive layer 164. The barrier layer 162 may conformally cover the conductive plugs 152, the bit line spacers 150, and the insulating capping layers 140. The barrier layer 162 may be formed through a deposition process. The barrier layer 162 may include a conductive metal nitride such as titanium nitride (TiN), tantalum nitride (TaN), and/or tungsten nitride (WN). The conductive layer 164 may be formed on the barrier layer 162 through a deposition process to cover the barrier layer 162. A thickness of the conductive layer 164 may be greater than a thickness of the barrier layer 162. The conductive layer 164 may include a metal material different from the barrier layer 162. The conductive layer 164 may include, for example, tungsten. Metal silicide layers may be further formed between the conductive plugs 152 and the landing layer LPz. The metal silicide layers may include cobalt silicide, nickel silicide, or manganese silicide.

The mask pattern 30P, the under pattern 40P, and the resist structure 50P may be formed on a first portion of the landing layer LPz. Forming the mask pattern 30P, the under pattern 40P, and the resist structure 50P may be performed by using a method described in the examples of FIGS. 1A to 3C. The landing layer LPz may correspond to the etching target layer 20 in FIG. 3C. The resist structure 50P may include the first resist pattern 51P and the second resist pattern 52P. The mask pattern 30P and the under pattern 40P may be formed through an etching process using the resist structure 50P as an etch mask. The mask pattern 30P and the resist structure 50P may expose a top surface of a second portion of the landing layer LPz. The resist structure 50P may further include the third resist pattern 53P described with reference to FIG. 5B. Thereafter, the resist structure 50P and the under pattern 40P may be removed.

Referring to FIGS. 7A and 7C, landing pads LP may be formed by etching the second portion of the landing layer LPz exposed by the mask pattern 30P. The landing pads LP may expose the insulating capping layers 140. Etching for forming the landing pads LP may be performed by using substantially the same method as etching for forming the target pattern 20P described in the examples of FIGS. 4A to 4C. The landing pads LP may correspond to the target pattern 20P described in the example of FIG. 4C. In the etching process, a portion of upper portions of the insulating capping layers 140 may be further removed. Each of the landing pads LP may include a barrier pattern 162P and a conductive pattern 164P. The barrier pattern 162P may be formed by etching the barrier layer 162. The conductive pattern 164P may be formed by etching the conductive layer 164. The landing pads LP may vertically overlap the conductive plugs 152. For example, the landing pads LP may partially overlap the conductive plugs 152. In this specification, “vertical” may mean parallel to the third direction D3.

The landing pads LP may be formed at positions corresponding to the resist structure 50P of FIG. 7B with substantially the same or similar pitch. The landing pads LP may have the same or similar shape and the same or similar size as the resist structure 50P. Because the first resist pattern 51P is formed through a EUV lithography process, the landing pads LP may be formed with a relatively small pitch P1. For example, the pitch P1 of the landing pads LP may be about 26 nm to about 39 nm. Accordingly, the semiconductor device may be miniaturized.

Because the resist structure 50P has improved LER characteristics, the landing pads LP may have improved LER characteristics. In addition, a deviation in sizes of the landing pads LP and a deviation in the pitch P1 of the landing pads LP may be small. The landing pads LP may have a uniform shape. For example, the landing pads LP may have a more uniform circular shape. According to one or more embodiments, because the landing pads LP are patterned using the resist structure 50P, a dose of a lithography process may be reduced. Accordingly, the productivity and efficiency of patterning the landing pads LP may be improved.

The landing pads LP may further include tin. The concentration of tin in the landing pads LP may be 1E11/cm³ or less. For example, the conductive pattern 164P may include tungsten and tin. The concentration of tin in the conductive pattern 164P may be less than the concentration of tungsten in the conductive pattern 164P. For example, the concentration of tin in the conductive pattern 164P may be 1E11/cm³ or less. For example, the barrier pattern 162P may include conductive metal nitride and tin. The concentration of tin in the barrier pattern 162P may be less than the concentration of conductive metal nitride in the barrier pattern 162P. For example, the concentration of tin in the barrier pattern 162P may be 1E11/cm³ or less.

Referring to FIGS. 7A and 7D, an insulating pattern 166 may be formed on the exposed insulating capping layers 140 and between the landing pads LP to cover side walls of the landing pads LP. The insulating pattern 166 may be disposed to surround the landing pads LP in a plan view. The landing pads LP may be electrically insulated from each other by the insulating pattern 166.

An upper insulating pattern 170 may be formed on the insulating pattern 166. The upper insulating pattern 170 may include a material having an etch selectivity with respect to the insulating pattern 166. For example, the upper insulating pattern 170 may include silicon nitride. The upper insulating pattern 170 may have openings penetrating the inside thereof, and the openings may expose the landing pads LP. For example, each of the openings may expose the corresponding first conductive pattern 164P.

A capacitor structure 180 may be formed on the upper insulating pattern 170 and the landing pads LP. The capacitor structure 180 may include a plurality of lower electrodes 181, a dielectric layer 183, and an upper electrode 189. The upper electrode 189 may include a semiconductor pattern 185 and a metal layer 187. The capacitor structure 180 may further include support patterns SPT.

The lower electrodes 181 may be respectively disposed on the landing pads LP. The plurality of lower electrodes 181 may each have a pillar shape or a cylinder shape. Bottom portions of the plurality of lower electrodes 181 may be disposed in the openings of the upper insulating pattern 170. The lower electrodes 181 may include metal, conductive metal nitride, or conductive metal oxide. The metal may include, for example, ruthenium (Ru), titanium (Ti), tantalum (Ta), niobium (Nb), iridium (Ir), molybdenum (Mo), and/or tungsten (W). The conductive metal nitride may include metal, titanium nitride (TiN), tantalum nitride (TaN), niobium nitride (NbN), molybdenum nitride (MoN), and/or tungsten nitride (WN). The conductive metal oxide may include conductive metal nitride, iridium oxide (IrO₂), ruthenium oxide (RuO₂), and/or strontium ruthenium oxide (SrRuO₃).

The support patterns SPT may be disposed on side walls of the lower electrodes 181. The support patterns SPT may be provided between two neighboring lower electrodes 181 among the lower electrodes 181 to maintain a constant distance between the two neighboring lower electrodes 181. The support patterns SPT may prevent the lower electrodes 181 from tilting or falling. The support patterns SPT may be vertically spaced apart from the two neighboring lower electrodes 181.

The dielectric layer 183 may be disposed on the lower electrodes 181. The dielectric layer 183 may be provided on the side walls of the lower electrodes 181, top surfaces and lower surfaces of the support patterns SPT, and the top surface of the upper insulating pattern 170. The dielectric layer 183 may conformally cover the side walls of the lower electrodes 181, the top surfaces and the lower surfaces of the support patterns SPT, and the top surface of the upper insulating pattern 170. The dielectric layer 183 may be a single layer or a multi-layer. The dielectric layer 183 may include a metal oxide, a dielectric material of a perovskite structure, and/or a combination thereof. The metal oxide may include, for example, HfO₂, ZrO₂, Al₂O₃, La₂O₃, Ta₂₀₃, and/or TiO₂. The dielectric material of the perovskite structure may include SrTiO₃ (STO), (Ba,Sr) TiO₃ (BST), BaTiO₃, PZT, and/or PLZT.

The semiconductor pattern 185 may be provided on the top surfaces and the side walls of the lower electrodes 181 and may cover the dielectric layer 183. Accordingly, the top surface of the semiconductor pattern 185 may extend in a horizontal direction, and the side surface of the semiconductor pattern 185 may extend in a vertical direction. The vertical direction may refer to a direction parallel to the lower surface of the substrate 110. For example, the top surface of the semiconductor pattern 185 may be substantially flat. The semiconductor pattern 185 may include at least one of an impurity-doped semiconductor material, a metal material, a metal nitride, and a metal silicide material. For example, the semiconductor pattern 185 may include silicon, germanium, and/or silicon-germanium.

A metal layer 187 may be disposed on the top and side surfaces of the semiconductor pattern 185. The metal layer 187 may include a flat top surface and a vertical side surface. For example, the metal layer 187 may include tungsten, but is not limited thereto.

Manufacturing of the semiconductor device 1 may be completed using the examples described so far. The semiconductor device 1 may be a memory device such as DRAM.

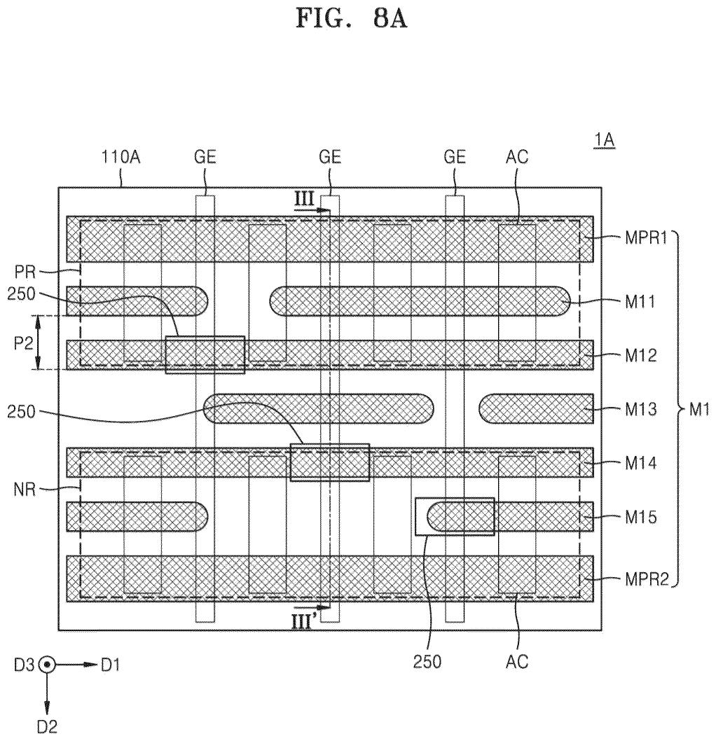

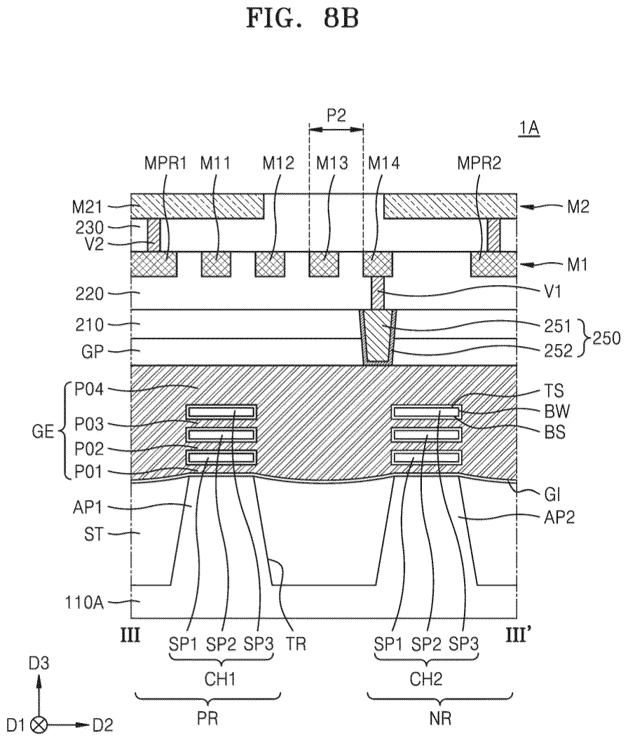

FIG. 8A is a plan view illustrating a layout of a semiconductor device 1A according to one or more embodiments. FIG. 8B is a cross-sectional view taken along line III-III′ of FIG. 8A according to one or more embodiment.

Referring to FIGS. 8A and 8B, the semiconductor device 1A may include a substrate 110A, the device isolation pattern ST, gate electrodes GE, a gate contact 250, a first conductive via V1, a first metal layer M1, second conductive vias V2, and a second metal layer M2.

The substrate 110A may be the same or similar to the substrate 100 of FIGS. 7A and 7B. However, the substrate 110A may have a logic cell area. Logic transistors may be disposed on the logic cell area of the substrate 110A to constitute logic circuits. For example, the logic cell area of the substrate 110A may include a logic p-type metal-oxide-semiconductor (MOS) field effect transistor (FET) (PMOSFET) region PR and an n-type MOSFET (NMOSFET) region NR. The PMOSFET region PR and the NMOSFET region NR may be spaced apart from each other in the second direction D2.

A trench TR may be formed in an upper portion of the substrate 110A to define a first active pattern AP1 and a second active pattern AP2. The first active pattern AP1 and the second active pattern AP2 may be provided on the PMOSFET region PR and NMOSFET region NR, respectively. Each of the first active pattern AP1 and the second active pattern AP2 may extend in the first direction D1. The first active pattern AP1 and the second active pattern AP2 may be vertically protruding portions of the substrate 110A.

The device isolation pattern ST may be provided in the trench TR to fill the trench TR. The device isolation pattern ST may include a silicon oxide layer. A first channel pattern CH1 may be provided on the first active pattern AP1. A second channel pattern CH2 may be provided on the second active pattern AP2. Each of the first channel pattern CH1 and the second channel pattern CH2 may include a first semiconductor pattern SP1, a second semiconductor pattern SP2, and a third semiconductor pattern SP3 which are sequentially stacked. The first semiconductor pattern SP1, the second semiconductor pattern SP2, and the third semiconductor pattern SP3 may be spaced apart from each other in a vertical direction (i.e., the third direction D3). The device isolation pattern ST may be spaced apart from the first channel pattern CH1 and the second channel pattern CH2. Each of the first semiconductor pattern SP1, the second semiconductor pattern SP2, and the third semiconductor pattern SP3 may include silicon (Si), germanium (Ge), or silicon-germanium (SiGe). For example, each of the first semiconductor pattern SP1, the second semiconductor pattern SP2, and the third semiconductor pattern SP3 may include crystalline silicon.

A plurality of first source/drain patterns may be provided on the first active pattern AP1. The first source/drain patterns may be spaced apart from each other in the first direction D1 with the first channel pattern CH1 therebetween. The first channel pattern CH1 may be disposed between a pair of first source/drain patterns. The first semiconductor pattern SP1, the second semiconductor pattern SP2, and the third semiconductor pattern SP3 which are stacked may connect the pair of first source/drain patterns to each other. A plurality of first recesses may be formed in an upper portion of the first active pattern AP1. The first source/drain patterns may be respectively provided the first recesses. The first source/drain patterns may be impurity areas of a first conductivity type (e.g., p-type).

A plurality of second source/drain patterns may be provided on the second active pattern AP2. The second channel pattern CH2 may be disposed between a pair of second source/drain patterns. The first semiconductor pattern SP1, the second semiconductor pattern SP2, and the third semiconductor pattern SP3 which are stacked may connect the pair of second source/drain patterns to each other. A plurality of second recesses may be formed in an upper portion of the second active pattern AP2. The second source/drain patterns may be respectively provided in the second recesses. The second source/drain patterns may be impurity areas of a second conductivity type (e.g., n-type).

The first source/drain patterns and the second source/drain patterns may be epitaxial patterns formed through a selective epitaxial growth (SEG) process.

The gate electrodes GE may extend in the second direction D2 across the first channel pattern CH1 and the second channel pattern CH2. The gate electrodes GE may be spaced apart from each other in the first direction D1. Each of the gate electrodes GE may be vertically over the first channel pattern CH1 and the second channel pattern CH2. The gate electrodes GE may include a conductive material such as metal. For example, each of the gate electrodes GE may include a plurality of stacked metal layers. Among the metal layers, two adjacent layers may include different metal materials.

Each of the gate electrodes GE may include a first portion PO1 disposed between the first active pattern AP1 or the second active pattern AP2 and the first semiconductor pattern SP1, a second portion PO2 disposed between the first semiconductor pattern SP1 and the second semiconductor pattern SP2, a third portion PO3 disposed between the second semiconductor pattern SP2 and the third semiconductor pattern SP3, and a fourth portion PO4 on the third semiconductor pattern SP3.

Each of the gate electrodes GE may be provided on a top surface TS, a bottom surface BS, and both side walls SW of each of the first semiconductor pattern SP1, the second semiconductor pattern SP2, and the third semiconductor pattern SP3. In other words, a transistor according to the embodiment may be a three-dimensional field effect transistor (e.g., multi-bridge channel FET (MBCFET™) or gate-all-around FET (GAAFET)) in which the gate electrodes GE three-dimensionally surround a channel. Hereinafter, for simplicity, a single gate electrode GE is described.

A gate capping pattern GP may be provided on the gate electrode GE to cover the gate electrode GE. The gate capping pattern GP may extend in the second direction D2 along the gate electrode GE. The gate capping pattern GP may include a material having etch selectivity to the first interlayer insulating layer 210 which is described below. For example, the gate capping pattern GP may include at least one of SiON, SiCN, SiCON, or SiN.

A gate insulating layer GI may be disposed between the gate electrode GE and the first channel pattern CH1 and between the gate electrode GE and the second channel pattern CH2. The gate insulating layer GI may cover the top surface TS, the bottom surface BS, and the both side walls SW of each of the first semiconductor pattern SP1, the second semiconductor pattern SP2, and the third semiconductor pattern SP3. The gate insulating layer GI may cover a top surface of the device isolation pattern ST below the gate electrode GE. The gate insulating layer GI may include silicon oxide, silicon oxynitride, and/or a high dielectric material.

The semiconductor device 1A may further include a first interlayer insulating layer 210. The first interlayer insulating layer 210 may be provided on the gate capping pattern GP to cover the gate capping pattern GP. The first interlayer insulating layer 210 may include, for example, a silicon oxide layer.

A pair of active contacts AC may be respectively provided on both sides of the gate electrode GE, as shown in FIG. 8A. In a plan view, the active contacts AC may have a bar shape extending in the second direction D2. The active contacts AC may penetrate the first interlayer insulating layer 210 and be electrically connected to the first source/drain patterns and the second source/drain patterns. The active contacts AC may each include a conductive material such as metal.

The gate contact 250 may be provided by penetrating the first interlayer insulating layer 210 and the gate capping pattern GP. The gate contact 250 may be provided on the gate electrode GE and electrically connected to the gate electrode GE. The gate contact 250 may include a first contact pattern 251 and a second contact pattern 252. For example, the first contact pattern 251 may include a metal such as aluminum, copper, tungsten, molybdenum, and/or cobalt. The second contact pattern 252 may cover side walls and a bottom surface of the first contact pattern 251. The second contact pattern 252 may function as a barrier pattern. The second contact pattern 252 may include metal nitride. The metal nitride may include at least one of titanium nitride (TiN), tantalum nitride (TaN), tungsten nitride (WN), nickel nitride (NiN), cobalt nitride (CON), or platinum nitride (PtN).

The semiconductor device 1A may further include a second interlayer insulating layer 220. The second interlayer insulating layer 220 may be formed on the first interlayer insulating layer 210 and the gate contact 250. The second interlayer insulating layer 220 may include, for example, silicon oxide, silicon nitride, and/or silicon oxynitride. The first conductive via V1 may be provided in the second interlayer insulating layer 220. The first conductive via V1 may be provided on the gate contact 250 and electrically connected to the gate contact 250. The first conductive via V1 may include, for example, metal.

The first metal layer M1 may be provided in the second interlayer insulating layer 220. The first metal layer M1 may include a first voltage wiring MPR1, a second voltage wiring MPR2, a first lower wiring M11, a second lower wiring M12, a third lower wiring M13, a fourth lower wiring M14, and a fifth lower wiring M15. The first voltage wiring MPR1, the second voltage wiring MPR2, the first lower wiring M11, the second lower wiring M12, the third lower wiring M13, the fourth lower wiring M14, and the fifth lower wiring M15 may be horizontally spaced apart from each other. At least one of the first voltage wiring MPR1, the second voltage wiring MPR2, the first lower wiring M11, the second lower wiring M12, the third lower wiring M13, the fourth lower wiring M14, and the fifth lower wiring M15 may be disposed on the first conductive via V1. At least one of the first voltage wiring MPR1, the second voltage wiring MPR2, the first lower wiring M11, the second lower wiring M12, the third lower wiring M13, the fourth lower wiring M14, and the fifth lower wiring M15 may be electrically connected to the gate contact 250 through the first conductive via V1.

The first voltage wiring MPR1 and the second voltage wiring MPR2 may extend in the first direction D1 as shown in FIG. 8A. The first voltage wiring MPR1 and the second voltage wiring MPR2 may be spaced apart from each other in the second direction D2. A drain voltage may be applied to one of first voltage wiring MPR1 and the second voltage wiring MPR2, and a source voltage may be applied to the other one of first voltage wiring MPR1 and the second voltage wiring MPR2. For example, the drain voltage may be applied to the first voltage line MPR1 and the source voltage may be applied to the second voltage line MPR2.

The first lower wiring M11, the second lower wiring M12, the third lower wiring M13, the fourth lower wiring M14, and the fifth lower wiring M15 may be disposed between the first voltage wiring MPR1 and the second voltage wiring MPR2. The first lower wiring M11, the second lower wiring M12, the third lower wiring M13, the fourth lower wiring M14, and the fifth lower wiring M15 may extend in the first direction D1. The first lower wiring M11, the second lower wiring M12, the third lower wiring M13, the fourth lower wiring M14, and the fifth lower wiring M15 may be spaced apart from each other in the second direction D2. The first lower wiring M11, the second lower wiring M12, the third lower wiring M13, the fourth lower wiring M14, and the fifth lower wiring M15 may have a second pitch P2. The second pitch P2 may be about 26 nm to about 39 nm. Accordingly, the semiconductor device 1A may be miniaturized.

The first voltage wiring MPR1, the second voltage wiring MPR2, the first lower wiring M11, the second lower wiring M12, the third lower wiring M13, the fourth lower wiring M14, and the fifth lower wiring M15 may be formed by using a method of forming the target pattern 20P described in the examples of FIGS. 1A to 4C or the examples of FIGS. 5A to 5C. The first voltage wiring MPR1, the second voltage wiring MPR2, the first lower wiring M11, the second lower wiring M12, the third lower wiring M13, the fourth lower wiring M14, and the fifth lower wiring M15 may correspond to the target pattern 20P described in the example of FIG. 4C. Processes of forming the first voltage wiring MPR1, the second voltage wiring MPR2, the first lower wiring M11, the second lower wiring M12, the third lower wiring M13, the fourth lower wiring M14, and the fifth lower wiring M15 may include performing a EUV lithography process. The first voltage wiring MPR1, the second voltage wiring MPR2, the first lower wiring M11, the second lower wiring M12, the third lower wiring M13, the fourth lower wiring M14, and the fifth lower wiring M15 may be substantially formed at the same time.

Because the first lower wiring M11, the second lower wiring M12, the third lower wiring M13, the fourth lower wiring M14, and the fifth lower wiring M15 are formed through a patterning process using the EUV lithography process, each of the first lower wiring M11, the second lower wiring M12, the third lower wiring M13, the fourth lower wiring M14, and the fifth lower wiring M15 may have a line shape with rounded corners. As shown in FIG. 8A, each of ends of the first lower wiring M11 may be rounded in a plan view. Each of ends of the third lower wiring M13 may have a rounded shape. Each of ends of the fifth lower wiring M15 may have a rounded shape.

The first voltage wiring MPR1, the second voltage wiring MPR2, the first lower wiring M11, the second lower wiring M12, the third lower wiring M13, the fourth lower wiring M14, and the fifth lower wiring M15 may include the same metal material. The first voltage wiring MPR1, the second voltage wiring MPR2, the first lower wiring M11, the second lower wiring M12, the third lower wiring M13, the fourth lower wiring M14, and the fifth lower wiring M15 may include copper (Cu), aluminum (Al), ruthenium (Ru), cobalt (Co), tungsten (W), and/or molybdenum (Mo). The first voltage wiring MPR1, the second voltage wiring MPR2, the first lower wiring M11, the second lower wiring M12, the third lower wiring M13, the fourth lower wiring M14, and the fifth lower wiring M15 may each further include tin. The concentration of tin in the first voltage wiring MPR1, the second voltage wiring MPR2, the first lower wiring M11, the second lower wiring M12, the third lower wiring M13, the fourth lower wiring M14, and the fifth lower wiring M15 may be 1E11/cm³ or less.

The semiconductor device 1A may further include a third interlayer insulating layer 230. A third interlayer insulating layer 230 may be provided on the second interlayer insulating layer 220 to cover the second interlayer insulating layer 220 and the first metal layer M1. For example, the third interlayer insulating layer 230 may cover the first voltage wiring MPR1, the second voltage wiring MPR2, the first lower wiring M11, the second lower wiring M12, the third lower wiring M13, the fourth lower wiring M14, and the fifth lower wiring M15. The third interlayer insulating layer 230 may include, for example, silicon oxide, silicon nitride, and/or silicon oxynitride.

The second conductive vias V2 may be provided in the third interlayer insulating layer 230 and on the first metal layer M1. Each of the second conductive vias V2 may be provided on and electrically connected to one of the first voltage wiring MPR1, the second voltage wiring MPR2, the first lower wiring M11, the second lower wiring M12, the third lower wiring M13, the fourth lower wiring M14, and the fifth lower wiring M15. The second conductive vias V2 may each include, for example, metal.

The second metal layer M2 may be provided in the third interlayer insulating layer 230 and on the second conductive vias V2. The second metal layer M2 may include upper wirings M21. Each of the upper wirings M21 may have a line shape extending in the second direction D2 in a plan view. The upper wirings M21 may be horizontally spaced apart from each other. The upper wirings M21 may be electrically connected to the corresponding wirings among the first voltage wiring MPR1, the second voltage wiring MPR2, the first lower wiring M11, the second lower wiring M12, the third lower wiring M13, the fourth lower wiring M14, and the fifth lower wiring M15 through the second conductive vias V2. The upper wirings M21 may each include metal such as copper (Cu), aluminum (Al), ruthenium (Ru), cobalt (Co), tungsten (W), and/or molybdenum (Mo).

Additional metal layers may be stacked on the third interlayer insulating layer 230. The metal layers may include routing wirings.

According to one or more embodiments, each of resist structures may include a first resist pattern and a second resist pattern and may be used as an etch mask. The second resist pattern may improve an LER of the first resist pattern. Because the second resist pattern is provided, each of the resist structures may have a more uniform width, a more uniform size, and a more uniform shape. Deviations in the size and the shape between the resist structures may be reduced. The productivity and efficiency of a pattern forming process may be improved.

Each of the embodiments provided in the above description is not excluded from being associated with one or more features of another example or another embodiment also provided herein or not provided herein but consistent with the disclosure.

While the disclosure has been particularly shown and described with reference to embodiments thereof, it will be understood that various changes in form and details may be made therein without departing from the spirit and scope of the following claims.

What is claimed is:

1. A method of forming a pattern, the method comprising:
forming an etching target layer on a substrate;
forming an under layer on the etching target layer;
forming a first resist pattern on the under layer;
forming a second resist layer covering a side wall and a top surface of the first resist pattern and extending on a top surface of the under layer;
forming a second resist pattern covering the side wall of the first resist pattern by removing a portion of the second resist layer on the top surface of the under layer; and
performing an etching process using a resist structure as an etch mask,
wherein the resist structure comprises the first resist pattern and the second resist pattern.

2. The method of claim 1, wherein the first resist pattern comprises a resist material, and
wherein the forming of the second resist layer comprises performing a deposition process using an extreme ultraviolet (EUV) resist material that is the same as the resist material of the first resist pattern.

3. The method of claim 1, wherein a width of the top surface of the first resist pattern is greater than a width of a middle portion of the first resist pattern,
wherein a width of a lower surface of the first resist pattern is greater than the width of the middle portion of the first resist pattern, and
wherein the second resist pattern covers a side wall of the middle portion of the first resist pattern.

4. The method of claim 1, wherein the forming of the first resist pattern comprises:
forming a first resist layer by performing a deposition process on the etching target layer; and
performing a EUV exposure process on the first resist layer, and
wherein an exposure process is not performed on the second resist layer.

5. The method of claim 4, wherein the forming of the first resist pattern comprises performing a first developing process using a first halogen gas on the first resist layer,
wherein the forming of the second resist pattern further comprises performing a second developing process using a second halogen gas on the second resist layer, and
wherein a concentration of the second halogen gas in the second developing process is less than a concentration of the first halogen gas in the first developing process.

6. The method of claim 5, wherein the second developing process is performed under a higher temperature condition than a temperature condition of the first developing process.

7. The method of claim 1, further comprising:
forming a third resist layer covering a side wall and a top surface of the second resist pattern and extending on the top surface of the under layer; and
forming a third resist pattern by removing a portion of the third resist layer on the top surface of the under layer,
wherein the resist structure further comprises the third resist pattern.

8. The method of claim 1, further comprising forming a target pattern by removing a portion of the etching target layer,
wherein a concentration of tin in the target pattern is 1E11/cm³ or less.

9. The method of claim 1, wherein the first resist pattern comprises tin oxide, and
wherein the second resist pattern comprises tin oxide.

10. A method of forming a pattern, the method comprising:
forming an etching target layer, an under layer, and a first resist pattern on a substrate, wherein the first resist pattern overlaps a first portion of the etching target layer and does not overlap a second portion of the etching target layer;
forming a second resist layer covering a side wall and a top surface of the first resist pattern and extending over the second portion of the etching target layer by performing a deposition process on the first resist pattern;
forming a second resist pattern by performing a developing process on the second resist layer; and
performing an etching process using the first resist pattern and the second resist pattern as an etch mask,
wherein the forming of the second resist pattern comprises removing the second resist layer that is over the second portion of the etching target layer.

11. The method of claim 10, wherein the first resist pattern comprises a resist material, wherein the forming of the second resist layer is performed using a same resist material as the resist material of the first resist pattern, and
wherein the second resist pattern is less dense than the first resist pattern.

12. The method of claim 10, wherein a difference between a maximum width and a minimum width of the second resist pattern is less than a difference between a maximum width and a minimum width of the first resist pattern.

13. The method of claim 10, wherein the forming of the first resist pattern comprises:
forming a first resist layer by performing a deposition process on the etching target layer;
performing an extreme ultraviolet (EUV) exposure process on the first resist layer;
performing a post exposure bake (PEB) process on the first resist layer; and
performing a first dry developing process on the first resist layer,
wherein the method further comprises performing a bake process on the second resist layer,
wherein the developing process on the second resist layer comprises a second dry developing process, and
wherein an exposure process is not performed on the second resist layer.

14. The method of claim 13, wherein the first dry developing process is performed under a temperature condition in a range of −10° C. to 10° C., and
wherein the second dry developing process is performed under a temperature condition in a range of 20° C. to 55° C.

15. The method of claim 13, wherein the first dry developing process is performed using a first halogen gas having a concentration in a range of 70% to 90%, and
wherein the second dry developing process is performed using a second halogen gas having a concentration in a range of 5% to 10%.

16. A method of manufacturing a semiconductor device, the method comprising:
forming a device isolation layer, direct contacts, bit lines, conductive plugs, a landing layer and an under layer on a substrate;
forming a mask pattern, an under pattern, and a resist structure on the landing layer; and
forming landing pads by etching the landing layer exposed by the mask pattern,
wherein the forming of the resist structure comprises:
forming a first resist pattern on the under layer;
forming a second resist layer covering a side wall and a top surface of the first resist pattern and extending on a top surface of the under layer; and
forming a second resist pattern covering the first resist pattern by removing a portion of the second resist layer on the top surface of the under layer.

17. The method of claim 16, wherein the resist structure comprises the first resist pattern and the second resist pattern, and
wherein the forming of the mask pattern comprises:
forming a mask layer on the landing layer; and
etching the mask layer.

18. The method of claim 16, wherein a pitch of the landing pads is in a range of 26 nm to 39 nm.

19. The method of claim 16, wherein each of the landing pads comprises tungsten and tin, and
wherein a concentration of tin in each of the landing pads is less than a concentration of tungsten in each of the landing pads.

20. The method of claim 19, wherein the concentration of tin in each of the landing pads is 1E11/cm³ or less.
